(19) United States
(12) Patent Application Publication
(10) Pub. No.: US 2004/0094840 A1
(43) Pub. Date: May 20, 2004

(54) Integrated circuit structure

(76) Inventors: Hitoshi Sakamoto, Hyogo (JP); Noriaki Ueda, Hyogo (JP); Takashi Sugino, Osaka (JP)

Correspondence Address: BIRCH STEWART KOLASCH & BIRCH, PO BOX 747, FALLS CHURCH, VA, 22040-0747, US

(21) Appl. No.: 10/472,462

(22) PCT Filed: Mar. 28, 2003
(86) PCT No.: PCT/JP02/03073

(30) Foreign Application Priority Data
Mar. 28, 2001 (JP) 2001-93501

(51) Int. Cl. H01L 23/48; H01L 23/52; H01L 29/40

(52) U.S. Cl. 257/758

(57) ABSTRACT

An interlayer dielectric multilayer film is formed by providing a boron nitride film as a protective film 34 between interlayer dielectric films 33 with a low relative dielectric constant which comprise organic coated films or porous films. The interlayer dielectric films 34 having a low relative dielectric constant are combined with the boron nitride film excellent in mechanical and chemical resistance, high in thermal conductivity and having a low relative dielectric constant, thereby achieving a low relative dielectric constant, while maintaining adhesion and moisture absorption resistance.

### TECHNICAL FIELD

This invention relates to an integrated circuit structure intended to achieve a low relative dielectric constant.

### BACKGROUND ART

In an integrated circuit, a silicon dioxide film (SiO₂ film) by the plasma CVD (chemical vapor deposition) method has so far been used as an interlayer dielectric film. However, because of high integration of transistors and speeding of a switching action, losses due to capacitance between wirings have posed a problem. To eliminate these losses, it is necessary to decrease the relative dielectric constant of the interlayer dielectric film, so that an interlayer dielectric film with a lower relative dielectric constant has been demanded. Under these circumstances, an organic coated film or a porous film with a low relative dielectric constant (for example, an organosilicon film or a film of amorphous carbon incorporating fluorine) is used as an interlayer dielectric film.

The conventional interlayer dielectric film can be provided with a very low relative dielectric constant (relative dielectric constant κ=2.5 or less). However, such film has been problematical in mechanical and chemical resistance and thermal conductivity. Adhesion of the film has also presented a problem, and its moisture absorption resistance has been a problem in terms of density. For these reasons, the low relative dielectric constant in the integrated circuit structure has not been realized.

The present invention has been accomplished in view of the above situations, and its object is to provide an integrated circuit structure which can achieve a low relative dielectric constant.

### DISCLOSURE OF THE INVENTION

The integrated circuit structure of the present invention is characterized by an interlayer dielectric multilayer film formed by providing a boron nitride film as a protective film between interlayer dielectric films.

Because of this feature, a low relative dielectric constant can be achieved, with adhesion and moisture absorption resistance being maintained, by combining interlayer dielectric films having a low relative dielectric constant with a boron nitride film excellent in mechanical and chemical resistance, high in thermal conductivity and having a low relative dielectric constant. As a result, it becomes possible to fulfill a demand for an interlayer dielectric multilayer film complying with the integrated circuit process which involves strict processing conditions.

Further, the integrated circuit structure of the present invention is characterized by an interlayer dielectric multilayer film formed by providing a boron carbonitride film as a protective film between interlayer dielectric films.

Because of this feature, a low relative dielectric constant can be achieved, with adhesion and moisture absorption resistance being maintained, by combining interlayer dielectric films having a low relative dielectric constant with a boron carbonitride film excellent in mechanical and chemical resistance, high in thermal conductivity and having a low relative dielectric constant. As a result, it becomes possible to fulfill a demand for an interlayer dielectric multilayer film complying with the integrated circuit process which involves strict processing conditions.

The integrated circuit structure of the present invention is also characterized in that the interlayer dielectric film is an organic coated film or a porous film having a relative dielectric constant κ of κ<2.2.

The protective film, which is a boron nitride film, is preferably formed by exciting mainly a nitrogen gas with a plasma, and then mixing the excited nitrogen gas with a diborane gas diluted with a hydrogen gas, thereby reacting them. The protective film, which is a boron nitride film, is also preferably formed by exciting mainly a nitrogen gas with a plasma, and then mixing the excited nitrogen gas with a boron chloride gas using a hydrogen gas as a carrier gas, thereby reacting them.

The protective film, which is a boron carbonitride film, is preferably formed by exciting mainly a nitrogen gas with a plasma, and then mixing the excited nitrogen gas with a diborane gas diluted with a hydrogen gas and an organic gas or a hydrocarbon-based gas, thereby reacting them. The protective film, which is a boron carbonitride film, is also preferably formed by exciting mainly a nitrogen gas with a plasma, and then mixing the excited nitrogen gas with a boron chloride gas using a hydrogen gas as a carrier gas and an organic gas or a hydrocarbon-based gas, thereby reacting them.

### BRIEF DESCRIPTION OF THE DRAWINGS

FIG. 1 is a schematic sectional view showing an integrated circuit structure according to an embodiment of the present invention. FIG. 2 is a schematic side view of a plasma CVD apparatus for forming a BN film or a BNC film.

### BEST MODE FOR CARRYING OUT THE INVENTION

To describe the present invention in more detail, the invention will be illustrated in accordance with the accompanying drawings.

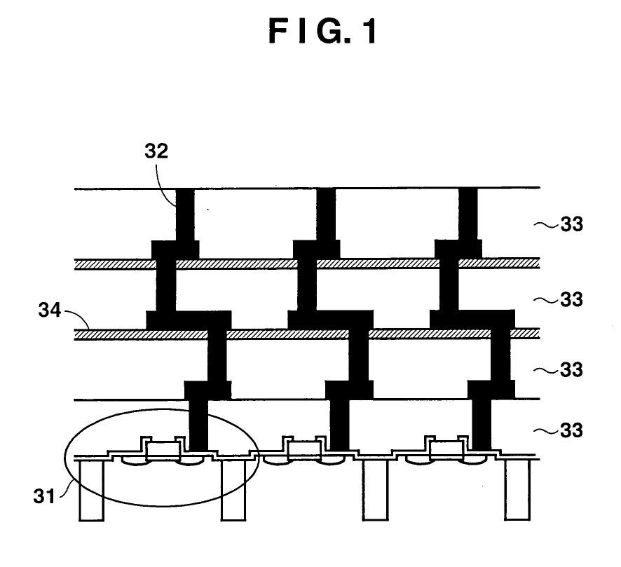

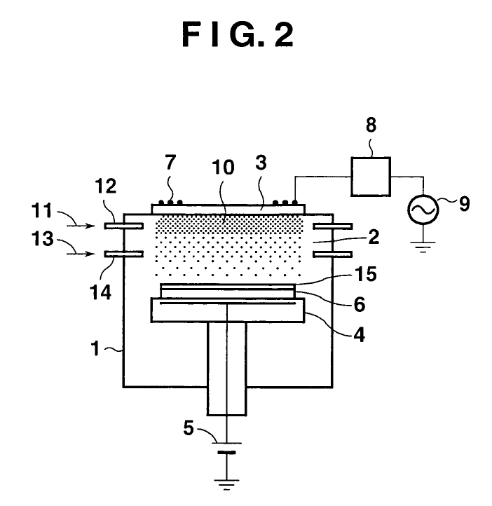

FIG. 1 shows a schematic section representing an integrated circuit structure according to an embodiment of the present invention.

In a highly integrated circuit (LSI) as an integrated circuit structure, as shown in the drawing, losses due to capacitance between wirings 32 are eliminated to achieve high integration of transistors 31 and speeding of a switching action. Thus, a film with a low relative dielectric constant (relative dielectric constant κ of <2.2) is used as an interlayer dielectric film 33 between the wirings 32 during the manufacturing process. An organic coated film or a porous film with a low relative dielectric constant is used as the interlayer dielectric film 33.

Further, a boron nitride (BN) film or a boron carbonitride (BNC) film is formed as a protective film 34 between the interlayer dielectric films 33 to make up an interlayer dielectric multilayer film. The interlayer dielectric film 33, which is an organic coated film or a porous film, has a low relative dielectric constant, but has been problematical in terms of mechanical and chemical resistance and thermal conductivity. Hence, a BN film or BNC film excellent in mechanical and chemical resistance, high in thermal conductivity and having a low relative dielectric constant is provided as the protective film 34. By so doing, it becomes possible to fulfill the demand for the interlayer dielectric film 33 complying with the LSI process, which involves strict processing conditions, while maintaining adhesion and moisture absorption resistance. Accordingly, an integrated circuit structure capable of achieving a low relative dielectric constant can be realized.

An apparatus for forming a BN film or a BNC film as the protective film 34 will be described with reference to FIG. 2. FIG. 2 is a schematic side view of a plasma CVD apparatus for forming a BN film or a BNC film.

As shown in the drawing, a film formation chamber 2 is formed within a cylindrical container 1, and a circular ceiling board 3 is provided in an upper part of the container 1. An electrostatic chuck 4, as a substrate holding portion, is provided in the film formation chamber 2 at the center of the container 1. A direct current power source 5 for the electrostatic chuck is connected to the electrostatic chuck 4 so that a substrate 6 of a semiconductor is electrostatically attracted thereto and held thereon.

A high frequency antenna 7 of a circular ring shape, for example, is disposed on the ceiling board 3, and a high frequency power source 9 is connected to the high frequency antenna 7 via a matching instrument 8. By supplying an electric power to the high frequency antenna 7, electromagnetic waves are shot into the film formation chamber 2 of the container 1. The electromagnetic waves shot into the container 1 ionize a gas within the film formation chamber 2 to generate a plasma 10.

The container 1 is provided with nitrogen gas nozzles 12 for introducing a nitrogen gas (N₂ gas) 11 (>99.999%) into the film formation chamber 2. Source gas nozzles 14 are provided for introducing a source gas 13 to the interior of the film formation chamber 2 below the nitrogen gas nozzles 12.

Informing a BN film as the protective film 34, a (B₂H₆) gas (1% to 5%) diluted with a hydrogen (H₂) gas, or a boron chloride (BCl₃: >99.999%) gas using an H₂ gas as a carrier gas is introduced as the source gas 13.

In forming a BNC film as the protective film 34, a (B₂H₆) gas (1% to 5%) diluted with a hydrogen (H₂) gas, and an organic gas (for example, a tetraethoxysilane (Si(O—C₂H₅)₄, hereinafter referred to as TEOS; ethanol, acetone or the like) gas or a hydrocarbon-based gas (for example, CH₄, C₂H₆, C₂H₄ or C₂H₂) are introduced as the source gas 13. Alternatively, a BCl₃ gas using an H₂ gas as a carrier gas, and an organic gas (for example, TEOS, ethanol, acetone or the like) gas or a hydrocarbon-based gas (for example, CH₄, C₂H₆, C₂H₄ or C₂H₂) are introduced as the source gas 13.

With the above-described plasma CVD apparatus, the N₂ gas 11 is introduced at a predetermined flow rate through the nitrogen gas nozzle 12, while the source gas 13 is introduced at a predetermined flow rate through the source gas nozzle 14. An electric power is supplied from the high frequency power source 9 to the high frequency antenna 7 to apply high frequency waves via the matching instrument 8. As a result, mainly the N₂ gas 11 is excited within the film formation chamber 2 to change into a plasma state. After the N₂ gas 11 is excited, it is mixed with the source gas 13 and reacted thereby, whereby a BN film or a BNC film is formed.

The interlayer dielectric film 33, which is an organic coated film or a porous film, and the protective film 34 were measured for voltage-capacitance, and the relative dielectric constant κ of <2.2 was confirmed to be obtained.

### Industrial Applicability

As described above, the present invention provides an integrated circuit structure, which can achieve a low relative dielectric constant, while maintaining adhesion and moisture absorption resistance, and which fulfills a demand for an interlayer dielectric multilayer film complying with the integrated circuit process involving strict processing conditions, by combining interlayer dielectric films having a low relative dielectric constant with a boron nitride film excellent in mechanical and chemical resistance, high in thermal conductivity and having a low relative dielectric constant.

1. An integrated circuit structure characterized by an interlayer dielectric multilayer film formed by providing a boron nitride film as a protective film between interlayer dielectric films.

2. An integrated circuit structure characterized by an interlayer dielectric multilayer film formed by providing a boron carbonitride film as a protective film between interlayer dielectric films.

3. The integrated circuit structure of claim 1 or 2, characterized in that the interlayer dielectric film is an organic coated film or a porous film having a relative dielectric constant κ of κ<2.2.
